(19) United States
(12) Patent Application Publication
(10) Pub. No.: US 2019/0280045 A1
(43) Pub. Date: Sep. 12, 2019

(54) ANNULAR 3-DIMENSIONAL MAGNETORESISTIVE DEVICES AND METHODS THEREFOR

(71) Applicant: Everspin Technologies, Inc., Chandler, AZ (US)

(72) Inventors: Sanjeev AGGARWAL, Scottsdale, AZ (US); Kevin Conley, San Jose, CA (US); Sarin A. Deshpande, Chandler, AZ (US)

(73) Assignee: Everspin Technologies, Inc., Chandler, AZ (US)

(21) Appl. No.: 16/293,729

(22) Filed: Mar. 6, 2019

Related U.S. Application Data
(60) Provisional application No. 62/640,716, filed on Mar. 9, 2018.

(51) Int. Cl. H01L 27/22; H01L 43/02; G11C 11/16

(52) U.S. Cl. CPC H01L 27/228; H01L 43/12; G11C 11/161; H01L 43/02

(57) ABSTRACT

A magnetoresistive device may include an annular-shaped magnetic tunnel junction (MTJ) bit having an inner end and an outer end. The MTJ bit may include an annular-shaped magnetically free region and an annular-shaped magnetically fixed region separated by an annular-shaped intermediate layer. A first electrical conductor may be in electrical contact with the inner end of the MTJ bit, and a second electrical conductor may be in electrical contact with the outer end of the MTJ bit.

### CROSS-REFERENCE TO RELATED APPLICATIONS

This application claims the benefit of priority from U.S. Provisional Application No. 62/640,716, filed on Mar. 9, 2018, which is incorporated by reference herein in its entirety.

### TECHNICAL FIELD

The present disclosure relates to, among other things, embodiments and aspects related to annular 3-dimensional magnetoresistive devices and methods of manufacturing such devices.

### INTRODUCTION

There are many inventions described and illustrated herein, as well as many aspects and embodiments of those inventions. In one aspect, the present disclosure relates to annular 3-dimensional (3D) magnetoresistive devices and methods of manufacturing such devices. In some embodiments, the disclosed 3D magnetoresistive devices may be 3D spin torque based devices. For example, the disclosed devices may be related to spin-transfer-torque (STT) magnetoresistive random access memory devices (MRAM), magnetoresistive sensor/transducer devices, etc. To describe aspects of the disclosed devices and methods, an exemplary magnetoresistive stack configuration is described. However, this is only exemplary, and the disclosed devices can have many other stack configurations, and the disclosed methods can be applied to manufacture magnetoresistive devices having all suitable magnetoresistive stacks.

Briefly, a magnetoresistive stack used in a memory device (e.g., a magnetoresistive random access memory (MRAM)) includes at least one non-magnetic layer (for example, at least one dielectric layer or a non-magnetic yet electrically conductive layer) disposed between a “fixed” magnetic region and a “free” magnetic region, each including one or more layers of ferromagnetic materials. Information is stored in the magnetoresistive memory stack by switching, programming, and/or controlling the direction of magnetization vectors in the magnetic layer(s) of the “free” magnetic region. The direction of the magnetization vectors of the “free” magnetic region may be switched and/or programmed (for example, through spin transfer torque) by application of a write signal (e.g., one or more current pulses) through the magnetoresistive memory stack. In contrast, the magnetization vectors in the magnetic layers of a “fixed” magnetic region are magnetically fixed in a predetermined direction. When the magnetization vectors of the “free” magnetic region adjacent to the non-magnetic layer (e.g., a dielectric layer) are in the same direction as the magnetization vectors of the “fixed” magnetic region adjacent to the non-magnetic layer, the magnetoresistive memory stack has a first magnetic state having a first electrical resistance. Conversely, when the magnetization vectors of the “free” magnetic region adjacent to the non-magnetic layer are opposite the direction of the magnetization vectors of the “fixed” magnetic region adjacent to the non-magnetic layer, the magnetoresistive memory stack has a second magnetic state having a second electrical resistance different from the first electrical resistance. The magnetic state of the magnetoresistive memory stack is determined or read based on the resistance of the stack in response to a read current.

### BRIEF DESCRIPTION OF THE DRAWINGS

Embodiments of the present disclosure may be implemented in connection with aspects illustrated in the attached drawings. These drawings show different aspects of the present disclosure and, where appropriate, reference numerals illustrating like structures, components, materials, and/or elements in different figures are labeled similarly. It is understood that various combinations of the structures, components, and/or elements, other than those specifically shown, are contemplated and are within the scope of the present disclosure.

For simplicity and clarity of illustration, the figures depict the general structure and/or manner of construction of the various described embodiments, as well as associated methods of manufacture. For ease of illustration, the figures depict the different regions along the thickness of the illustrated stacks as a layer having well-defined boundaries with straight edges (e.g., depicted using lines). However, one skilled in the art would understand that, in reality, at an interface between adjacent regions or layers, the materials of these regions may alloy together, or migrate into one or the other material, and make their boundaries ill-defined or diffuse. That is, although multiple layers with distinct interfaces are illustrated in the figures, in some cases, over time and/or exposure to high temperatures, materials of some of the layers may migrate into or interact with materials of other layers to present a more diffuse interface between these layers. Further, although the figures illustrate each region or layer as having a relatively uniform thickness across its width, one of ordinary skill in the art would recognize that, in reality, the different regions may have a non-uniform thickness (e.g., the thickness of a layer may vary along the width of the layer), and/or the thickness of one region or layer may differ relative to the thickness of another (e.g., adjacent) region or layer.

In the figures and description, details of well-known features (e.g., interconnects, etc.) and manufacturing techniques (e.g., deposition techniques, etching techniques, etc.) may be omitted for the sake of brevity (and to avoid obscuring other features and details), since these features/technique are well known to those of ordinary skill in the art. Elements in the figures are not necessarily drawn to scale. The dimensions of some features may be exaggerated relative to other features to improve understanding of the exemplary embodiments. Cross-sectional views are simplifications provided to help illustrate the relative positioning of various regions/layers and to describe various processing steps. One skilled in the art would appreciate that the cross-sectional views are not drawn to scale and should not be viewed as representing proportional relationships between different regions/layers. Moreover, while certain regions/layers and features are illustrated with straight 90-degree edges, in reality, such regions/layers may be more “rounded” and/or gradually sloping. It should also be noted that, even if it is not specifically mentioned, aspects described with reference to one embodiment may also be applicable to, and may be used with, other embodiments.

FIG. 1 is a cross-sectional schematic illustration of the structure of an exemplary annular 3-dimensional magnetoresistive device of the current disclosure;

FIG. 2 is a schematic illustration of a top view of the annular structure of an exemplary magnetoresistive bit of the device of FIG. 1;

FIGS. 3A-3D are cross-sectional schematic illustrations of exemplary magnetoresistive stacks/structures of the magnetoresistive bit of FIG. 2;

FIG. 4 is a perspective view of an array of vertically stacked magnetoresistive bits of the device of FIG. 1 in an exemplary embodiment;

FIG. 5 is a flow chart illustrating an exemplary fabrication process of the magnetoresistive device of FIG. 1;

FIGS. 6A-6H are cross-sectional schematic illustrations depicting the magnetoresistive device of FIG. 1 after various process steps in the fabrication process of FIG. 5;

FIG. 7 is a flow chart illustrating another exemplary fabrication process of a magnetoresistive device of the current disclosure;

FIGS. 8A-8J are cross-sectional schematic illustrations depicting the magnetoresistive device of FIG. 1 after various process steps in the fabrication process of FIG. 7;

FIG. 9 is a schematic diagram of an exemplary magnetoresistive memory element electrically connected in a magnetoresistive memory cell configuration;

FIG. 10A is a schematic block diagram illustrating an exemplary discrete memory device that includes an exemplary magnetoresistive device of the current disclosure;

and

FIG. 10B is a schematic block diagram illustrating an exemplary embedded memory device that includes an exemplary magnetoresistive device of the current disclosure.

There are many embodiments described and illustrated herein. The present disclosure is neither limited to any single aspect nor embodiment thereof, nor to any combinations and/or permutations of such aspects and/or embodiments. Each of the aspects of the present disclosure, and/or embodiments thereof, may be employed alone or in combination with one or more of the other aspects of the present disclosure and/or embodiments thereof. For the sake of brevity, many of those combinations and permutations are not discussed separately herein.

### DETAILED DESCRIPTION

It should be noted that all numeric values disclosed herein (including all disclosed thickness values, limits, and ranges) may have a variation of ±10% (unless a different variation is specified) from the disclosed numeric value. For example, a layer disclosed as being “t” units thick can vary in thickness from (t−0.1t) to (t+0.1t) units. Further, all relative terms such as “about,” “substantially,” “approximately,” etc. are used to indicate a possible variation of ±10% (unless noted otherwise or another variation is specified). Moreover, in the claims, values, limits, and/or ranges of the thickness and atomic composition of, for example, the described layers/regions, means the value, limit, and/or range±10%.

It should be noted that the description set forth herein is merely illustrative in nature and is not intended to limit the embodiments of the subject matter, or the application and uses of such embodiments. Any implementation described herein as exemplary is not to be construed as preferred or advantageous over other implementations. Rather, the term “exemplary” is used in the sense of example or “illustrative,” rather than “ideal.” The terms “comprise,” “include,” “have,” “with,” and any variations thereof are used synonymously to denote or describe a non-exclusive inclusion. As such, a device or a method that uses such terms does not include only those elements or steps, but may include other elements and steps not expressly listed or inherent to such device and method. Further, the terms “first,” “second,” and the like, herein do not denote any order, quantity, or importance, but rather are used to distinguish one element from another. Similarly, terms of relative orientation, such as “top,” “bottom,” “left,” “right,” etc. are used with reference to the orientation of the structure(s) illustrated in the figures being described. Moreover, the terms “a” and “an” herein do not denote a limitation of quantity, but rather denote the presence of at least one of the referenced item.

In this disclosure, the term “region” is used generally to refer to one or more layers of material. That is, a region (as used herein) may include a single layer (or film or coating) of material or multiple layers or coatings (or films) of materials stacked one on top of another to form a multi-layer system. Further, although in the description below, the different regions in the disclosed stack are sometimes referred to by specific names (such as, e.g., capping layer, reference layer, free layer, fixed layer, tunnel barrier layer, transition layer, etc.), this is only for ease of description and not intended as a functional description of the layer.

In one exemplary aspect, an annular 3D magnetoresistive device of the present disclosure may be a magnetic tunnel junction type device (MTJ device). The MTJ device may be implemented, for example, as a spin-torque magnetoresistive random access memory (“MRAM”) element (“memory element”), a magnetoresistive sensor, a magnetoresistive transducer, etc. An MTJ device typically includes a magnetoresistive stack/structure that includes intermediate layers positioned (or sandwiched) between ferromagnetic regions/layers. The intermediate layers may be made of dielectric materials and function as tunnel barriers in some embodiments. In other embodiments, the intermediate layers may be made of conductive materials (including, but not limited to, a non-magnetic conductive material such as, e.g., copper, gold, or alloys thereof) to form a giant magnetoresistive (GMR) or GMR-type device. It is also contemplated that, in some embodiments, the annular 3D magnetoresistive device of the present disclosure may be an anisotropic magnetoresistance (AMR) type device.

In one aspect, the annular 3D magnetoresistive devices of the current disclosure include annular 3D magnetic tunnel junction bits (MTJ bits). These MTJ bits may be formed from a magnetoresistive stack/structure that may include, or may be operably coupled to, one or more electrically conductive electrodes, vias, or conductors on either side of the magnetoresistive stack/structure. As described in further detail below, the magnetoresistive stack/structure that forms the annular 3D MTJ bits may include many different regions or layers of material, where some of the layers include magnetic materials, whereas others do not. In one embodiment, the methods of manufacturing the disclosed devices may include sequentially depositing, growing, sputtering, evaporating, and/or providing (collectively referred herein as “depositing” or other verb tense (e.g., “deposit” or “deposited”)) layers and regions which, after further processing (for example, etching) form an annular MTJ bit. While the following written description relates to MTJ bits stacked on top of one another to form a 3D magnetoresistive device, those of ordinary skill in the art will readily understand that the present disclosure is not limited to only 3D magnetoresistive devices.

The magnetoresistive stacks/structures that form the annular MTJ bits may be formed between a first electrode/via/line and a second electrode/via/line, both of which may permit electrical access to the MTJ bit by allowing for electrical connectivity to circuitry and other elements of the magnetoresistive device. Between the electrodes/vias/lines are regions (each made of a single layer or multiple layers) of different materials. The magnetoresistive stack/structure that forms the MTJ bits may include at least one “fixed” magnetic region (which may include, among other things, a plurality of ferromagnetic layers), at least one “free” magnetic region (which may include, among other things, a plurality of ferromagnetic layers), and one or more intermediate regions disposed between a “fixed” magnetic region and the “free” magnetic region. In some embodiments, the one or more intermediate regions may be made of dielectric materials. However, in other embodiments, the one or more intermediate regions may be made of electrically conductive materials. In some embodiments, the electrode/via/line on one or both sides of the magnetoresistive stack/structure may be eliminated, and an interconnect (e.g., bit line) may be formed in contact with the magnetoresistive stack/structure.

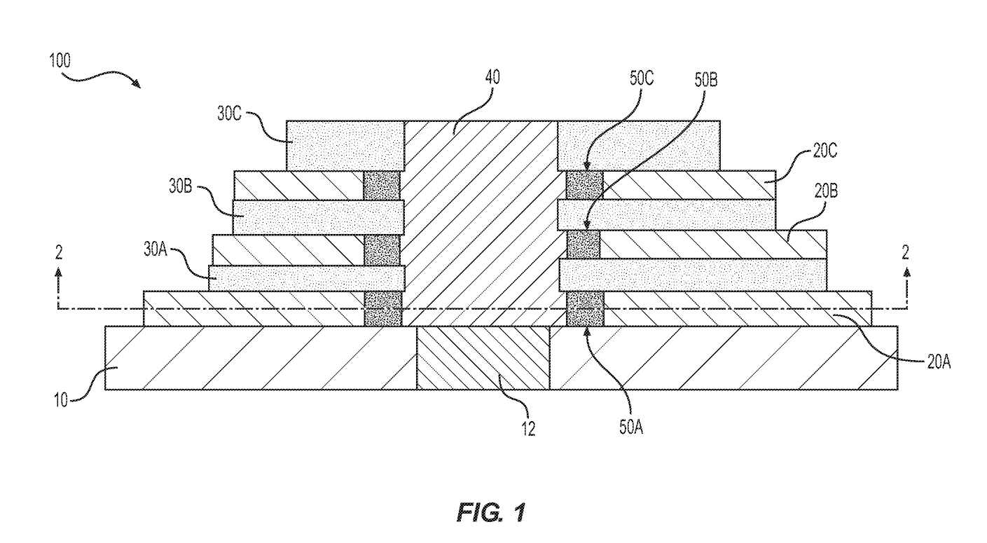

FIG. 1 illustrates a cross-sectional view of an exemplary annular 3D magnetoresistive device 100 of the present disclosure. As described previously, the relative dimensions of the different features of FIG. 1 (and subsequent figures) is only exemplary. The magnetoresistive device 100 illustrated in FIG. 1 includes three vertically spaced-apart ring-shaped or annular MTJ bits 50A, 50B, 50C separated from each other by dielectric regions 30A and 30B. Another dielectric region 30C is disposed on or above MTJ bit 50C. That is, as illustrated in FIG. 1, MTJ bits 50A and 50B are separated from each other by a dielectric region 30A, MTJ bits 50B and 50C are separated from each other by a dielectric region 30B, and MTJ bit 50C is separated from circuitry above (e.g., another magnetoresistive stack, interconnects, etc.) by a dielectric region 30C. It should be noted that although FIG. 1 illustrates three annular MTJ bits stacked one on top of another, this is only exemplary. In general, any number of annular MTJ bits (e.g., 2, >2, 4, 5, 6, 7, 8, >8, etc.) may be stacked one on top of another with dielectric layers/regions isolating at least some of the adjacent MTJ bits.

As illustrated in FIG. 1, the vertically stacked MTJ bits 50A, 50B, 50C are formed on a surface of an integrated circuit (IC 10) such that a first end of each bit 50A, 50B, 50C is in electrical contact with a metal pad 12 (interconnect, via, line, etc.) of IC 10 through a conductive via 40. As known to those having ordinary skill in the art, metal pad 12 may be in electrical connection with circuits (e.g., one or more transistors) formed on IC 10. Conductive regions 20A, 20B, and 20C provide electrical contact to a second end of each of MTJ bits 50A, 50B, 50C, respectively. In the embodiment illustrated in FIG. 1, the inner end of each ring-shaped MTJ bit 50A, 50B, and 50C is the first end that is in contact with conductive via 40 and the outer end is of each ring-shaped MTJ bit 50A, 50B, 50C is the second end that is in contact with conductive regions 20A, 20B, and 20C. In some embodiments, the conductive regions 20A, 20B, and 20C will be electrically isolated from each other so that each MTJ bit 50A, 50B, 50C may be selectively accessed. For example, MTJ bit 50A can be accessed by passing a signal through conductive region 20A, MTJ bit 50B can be accessed by passing a current through conductive region 20B, and MTJ bit 50C can be accessed by passing a current through conductive region 20C.

In general, magnetoresistive device 100 may include a device in any stage of processing, and the MTJ bits may be formed on any metal layer (or between any two metal layers) of magnetoresistive device 100. For example, in some embodiments, the vertically stacked MTJ bits 50A, 50B, 50C may be formed on the M1 metal layer (not shown), the M2 metal layer (not shown), or any other layer of magnetoresistive device 100. Although not illustrated in FIG. 1, magnetoresistive device 100 may also include structures formed on top of the MTJ bits. For example, the vertically stacked MTJ bits 50A, 50B, and 50C may be formed between two metal layers (e.g., between metal layers M2 and M3, etc.) of magnetoresistive device 100. In such an embodiment, an MTJ bit may be accessed via metal layers M2 and M3 of magnetoresistive device 100.

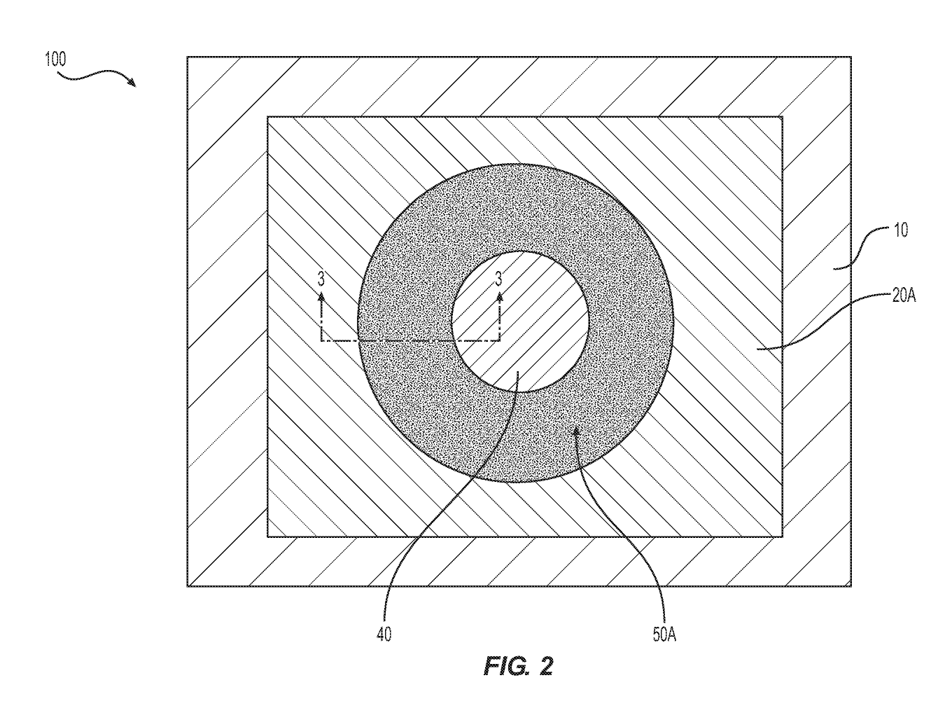

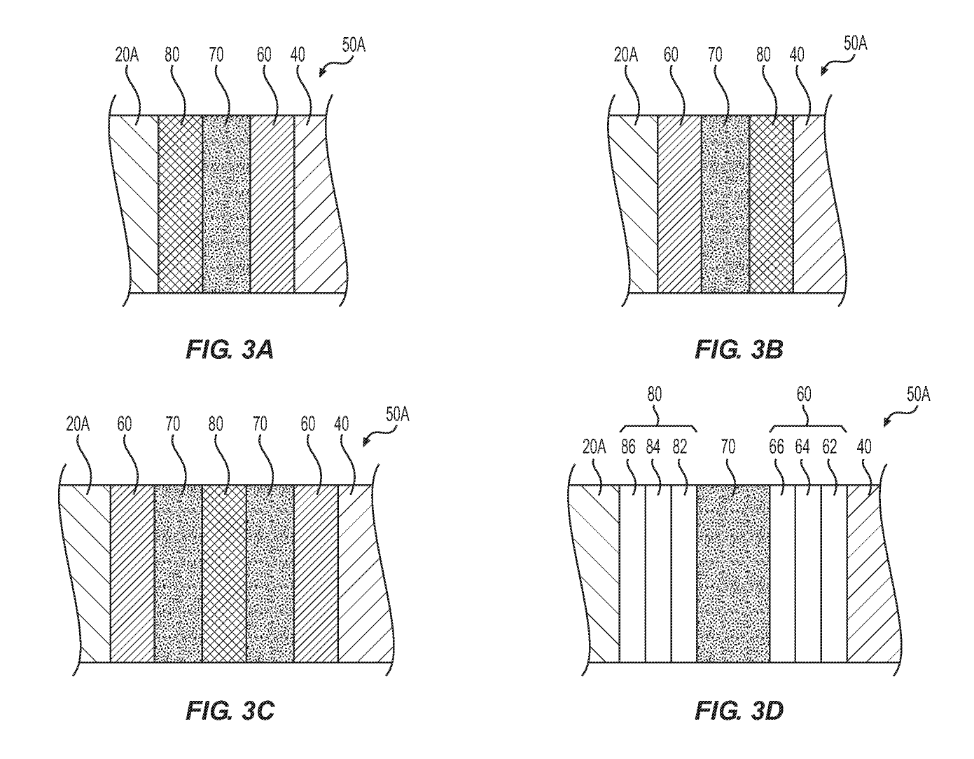

FIG. 2 is a cross-sectional view of magnetoresistive device 100 along plane 2-2 (see FIG. 1) showing the annular structure of MTJ bit 50A, and FIGS. 3A-3D depict cross-sectional views of various exemplary magnetoresistive stacks/structures that may make up a single MTJ bit 50A, as viewed from the perspective of plane 3-3 (see FIG. 2). In the discussion below, reference will be made to FIG. 1 and FIGS. 3A-3D. MTJ bits 50A, 50B, 50C may be any type of in-plane or out-of-plane (i.e., perpendicular) magnetically anisotropic MTJ bits, and may include any type of now-known or later developed magnetoresistive stack/structure. In general, MTJ bits 50A, 50B, 50C may all be the same type of MTJ bit, or may be different types of MTJ bits. FIGS. 3A-3D illustrate some exemplary magnetoresistive stacks/structures (hereinafter referred to as magnetoresistive stack or just stack) that may serve as one or more of the MTJ bits 50A, 50B, 50C of device 100. In some embodiments, MTJ bits 50A, 50B, 50C may have one of the exemplary stacks shown as FIG. 3A, 3B, 3C, or 3D. In general, the multi-layer stack of MTJ bits 50A, 50B, 50C may comprise at least one “fixed” magnetic region 60 (hereinafter referred to as “fixed region 60”), at least one “free” magnetic region 80 (hereinafter referred to as “free region 80”), and at least one intermediate region 70 disposed between the fixed region 60 and the free region 80. The term “free” refers to ferromagnetic regions having a magnetic moment that may shift or move significantly in response to applied magnetic fields or spin-polarized currents used to switch the magnetic moment vector of a “free” region. And, the term “fixed” refers to ferromagnetic regions having a magnetic moment vector that does not move substantially in response to such applied magnetic fields or spin-polarized currents.

With renewed reference to FIGS. 2 and 3A-3D, MTJ bit 50A (and/or MTJ bits 50B and 50C) may include a first exemplary multi-layer annular structure shown in FIG. 3A. For example, MTJ bit 50A may include a fixed region 60 forming an inner annular ring, free region 80 forming an outer annular ring, and intermediate region forming an annular ring positioned between fixed region 60 and free region 80. Fixed region 60 may include one or more layers of ferromagnetic alloys (comprising, e.g., some or all of cobalt, iron, nickel, and boron, etc.), and free region 80 may comprise one or more layers of ferromagnetic alloys (comprising e.g., nickel, iron, cobalt, etc.), in some cases separated by a coupling layer (comprising, e.g., tantalum, tungsten, molybdenum, ruthenium, rhodium, rhenium, iridium, chromium, osmium, etc.). As a person of ordinary skill in the art would recognize, many commonly used layers (e.g., seed layers, transition layers, reference layers, etc.) are not shown in the exemplary stacks of FIGS. 3A-3D for the sake of clarity.

The fixed, intermediate, and free regions may be formed in any order. That is, in some embodiments, as illustrated in FIG. 3B, for example, free region 80 may form the inner annular ring and the fixed region 60 may form the outer annular ring of the multi-layer annular structure. In some embodiments, as illustrated in FIG. 3C, for example, the MTJ bits may have two fixed regions 60 positioned on either side of a free region 80 with intermediate regions 70 positioned between the fixed regions 60 and free region 80. In some embodiments, as illustrated in FIG. 3D, for example, fixed region 60 may include multiple ferromagnetic layers 62, 66 separated by an antiferromagnetic (AF) coupling layer 64, and/or free region 80 may include a plurality of ferromagnetic layers 82 and 86 separated by an AF coupling layer 84. Although not illustrated, one or both of free region 80 and fixed region 60 may include additional layers, such as, for example, reference layers, insertion layers, and/or transition layers.

It should be noted that, although exemplary stacks that comprise different distinct regions of layers are illustrated in FIGS. 3A-3D, this is only exemplary. As known to one skilled in the art, the interface between adjacent regions of a stack may, in some cases, be characterized by compositional (e.g., chemical) and/or structural changes due to intermixing between the materials (or intermetallic formation) of the adjacent regions (e.g., during deposition, post deposition anneal, etc.). For example, while the compositional profile across an ideal interface (i.e., an interface which does not undergo compositional changes) between two regions (or layers) may indicate a sharp profile (i.e., the composition abruptly changes from the composition of one region to that of the other region), the compositional profile across a typical interface of the stacks of FIGS. 3A-3D may indicate a different profile. For example, the profile may indicate a gradual change in chemical composition across an interface of two regions if intermixing occurs between the materials of the regions, or the profile across the interface may indicate the presence of a different composition in the vicinity of the interface if a different interfacial phase (e.g., an intermetallic) is formed at the interface.

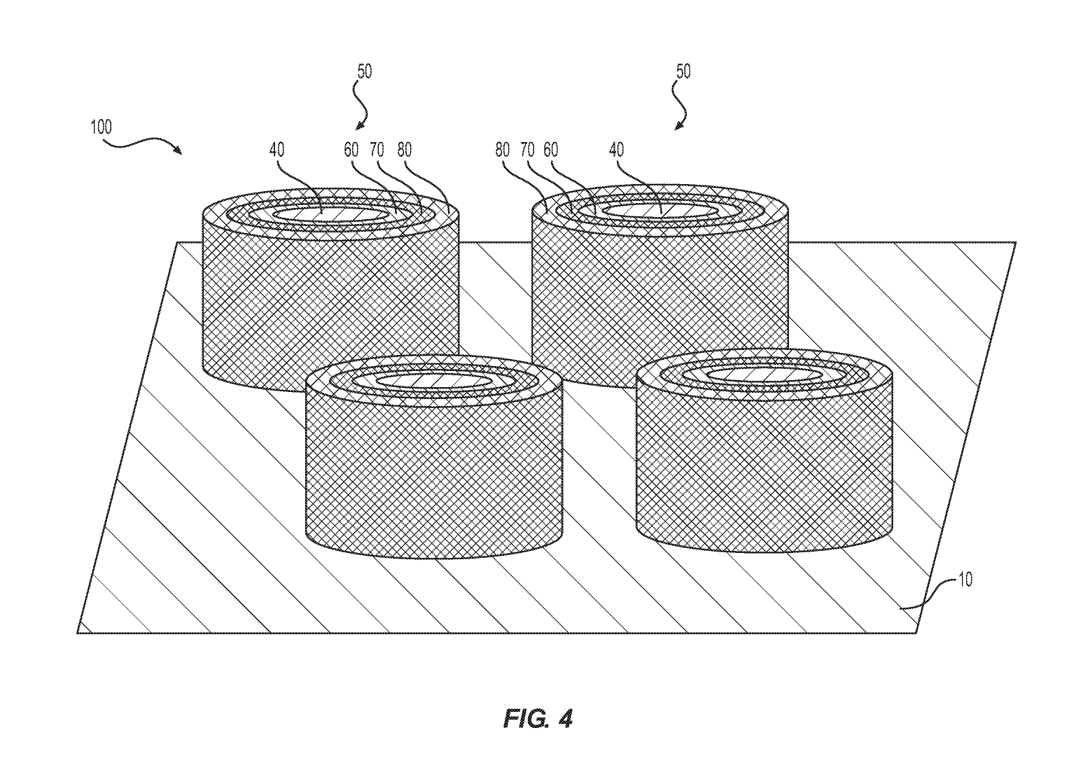

The stacks shown in FIGS. 3A-3D are only exemplary and MTJ bits 50A, 50B, 50C may have any now-known or future developed stack (including one or more synthetic antiferromagnetic (SAF) structures, synthetic ferromagnetic (SyF) structures, etc.). U.S. Pat. Nos. 8,686,484; 8,747,680; 9,023,216; 9,136,464; and 9,419,208, and U.S. patent application Ser. No. 15/831,736 (filed Dec. 5, 2017); 62/591,945 (filed Nov. 29, 2017); 62/594,229 (filed Dec. 4, 2017); 62/580,612 (filed Nov. 2, 2017); 62/582,502 (filed Nov. 7, 2017), and 62/588,158 (filed Nov. 17, 2017) describe exemplary magnetoresistive stacks that may also serve as MTJ bits 50A, 50B, 50C in some embodiments. These references are incorporated by reference in their entirety herein. In some embodiments, some of the MTJ bits (e.g., MTJ bits 50A and 50C) may have one structure (e.g., the structure depicted in FIG. 3A) and some of the MTJ bits (e.g., MTJ bit 50B) may have a different structure (e.g., the structure shown in FIG. 3D). However, in some embodiments, all the MTJ bits of device 100 may have the same structure. In the discussion below, for the sake of simplicity, MTJ bits 50A, 50B, and 50C are assumed to have the structure illustrated in FIG. 3A, and are collectively referred to as MTJ bit 50. However, it should be noted that this is only exemplary, and as explained above, these MTJ bits can have any suitable structure. It should be noted that, although FIGS. 1-3D illustrate a single column of three vertically stacked annular MTJ bits (i.e., MTJ bits 50A, 50B, and 50C), in reality, as illustrated in FIG. 4, an array of such vertically stacked annular MTJ bits may be formed on integrated circuit 10 at any desired pitch.

With renewed reference to FIG. 1, the vertically stacked annular MTJ bits 50A, 50B, 50C are separated by dielectric regions 30A, 30B, 30C that function to electrically isolate the individual MTJ bits. Any now-known or future-developed electrically insulating material (oxide, nitride, carbonitride, etc.) may be used as dielectric materials 30A, 30B, 30C. In some embodiments, the dielectric materials of regions 30A, 30B, and 30C may include one or more of Silicon Nitride (e.g., Si₃N₄, SiN, etc.), Silicon Oxide (e.g., SiO₂, SiOₓ, etc.), a low-k ILD material (e.g., carbon doped SiO₂ (SiOC), Carbon Doped Oxide (CDO), Organo Silicate Glass (OSG) spin-on organics, etc.), aluminum oxide (such as Al₂O₃), magnesium oxide (such as MgO), tetraethoxysilane (TEOS), and/or one or more combinations thereof. In some embodiments, each of dielectric regions 30A, 30B, 30C may include the same or similar material. In other embodiments, at least one of dielectric regions 30A, 30B, 30C includes a material that is different (e.g., a material that includes a different property or characteristic) from the material of the other dielectric regions. For example, dielectric region 30A may be formed of a single dielectric material (e.g., TEOS), dielectric region 30B may be formed of a single dielectric material (same or different from the material of region 30A), etc. However, this is not a requirement. In some embodiments, one or more of regions 30A, 30B, 30C may include multiple materials (e.g., deposited one atop another, deposited in different regions, or deposited as a composition etc.). In some embodiments, dielectric regions 30A, 30B, and 30C may be formed of the same material (or material set). That is, dielectric regions 30A, 30B, and 30C may all include, for example, one or more of SiO₂, SiN, SiOC, TEOS, etc. For the sake of simplicity, in the discussion below, dielectric regions 30A, 30B, and 30C are assumed to include the same material set, and are collectively referred to as dielectric region 30.

Conductive regions 20A, 20B, and 20C that form individual electrical connections with one end (e.g., a radially outer peripheral end in FIG. 1) of MTJ bits 50A, 50B, and 50C may be formed of any electrically conductive material. Conductive via 40 that forms a common electrical connection with the opposite end (e.g., a radially innermost end) of all MTJ bits 50A, 50B, and 50C may also be formed of any electrical conductive material. In some embodiments, one or more of Copper (Cu), Tantalum (Ta), Tantalum Nitride (TaN), Aluminum (Al), Titanium (Ti), Tungsten (W), etc. may be used to form conductive regions 20A, 20B, 20C and/or conductive via 40. In some embodiments, conductive regions 20A, 20B, 20C may include the same material or material set. For example, each of conductive regions 20A, 20B, and 20C may be formed of one of more of Cu, Ta, TaN, Al, Ti, etc. By way of example, in the discussion below, conductive regions 20A, 20B, and 20C are assumed to include (or otherwise formed from) the same material set, and are collectively referred to as conductive region 20.

Methods of fabricating an exemplary magnetoresistive device 100 (e.g., magnetoresistive device 100 of FIG. 1) will now be described. It should be appreciated that the described methods are merely exemplary. In some embodiments, the methods may include a number of additional or alternative steps, and in some embodiments, one or more of the described steps may be omitted. Any described step may be omitted or modified, or other steps added, as long as the intended functionality of the fabricated magnetoresistive device remains substantially unaltered. Further, although a certain order is described or implied in the described methods, in general, the steps of the described methods need not be performed in the illustrated and described order. Further, the described methods may be incorporated into a more comprehensive procedure or process having additional functionality not described herein.

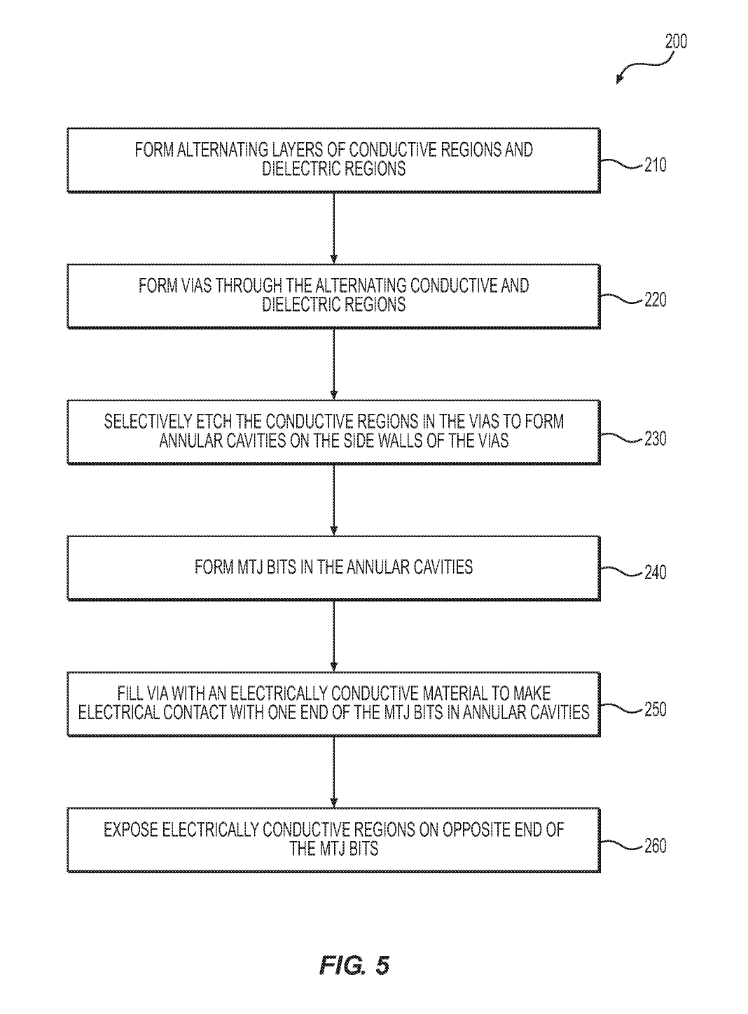

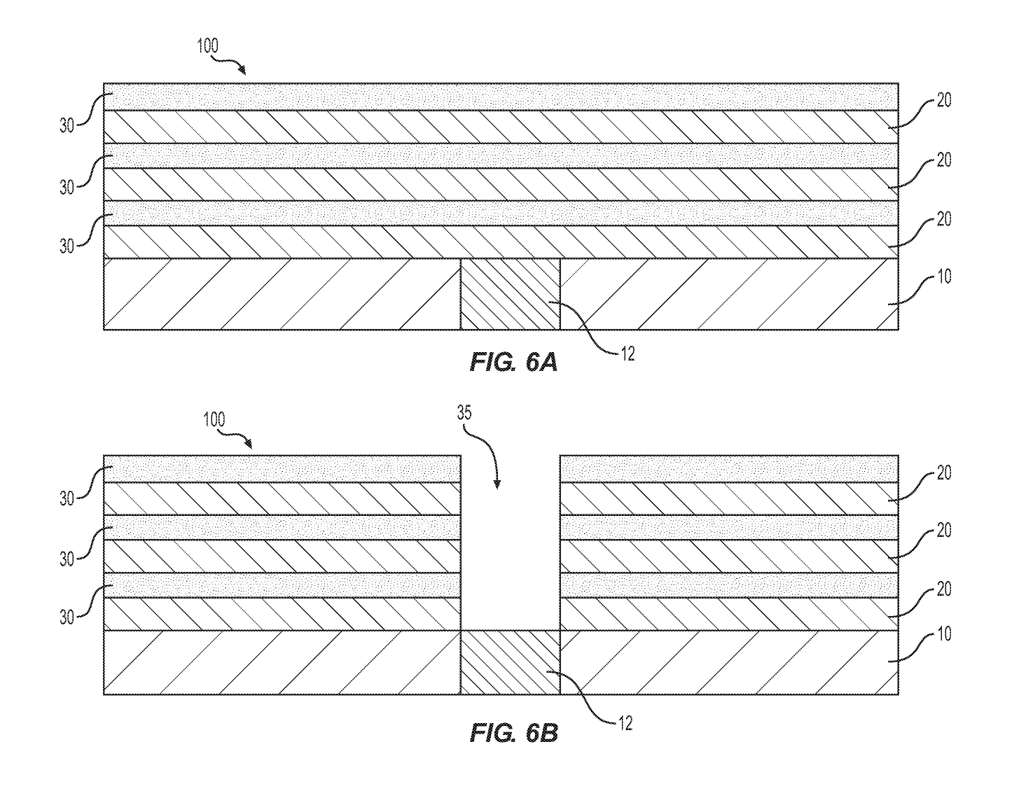

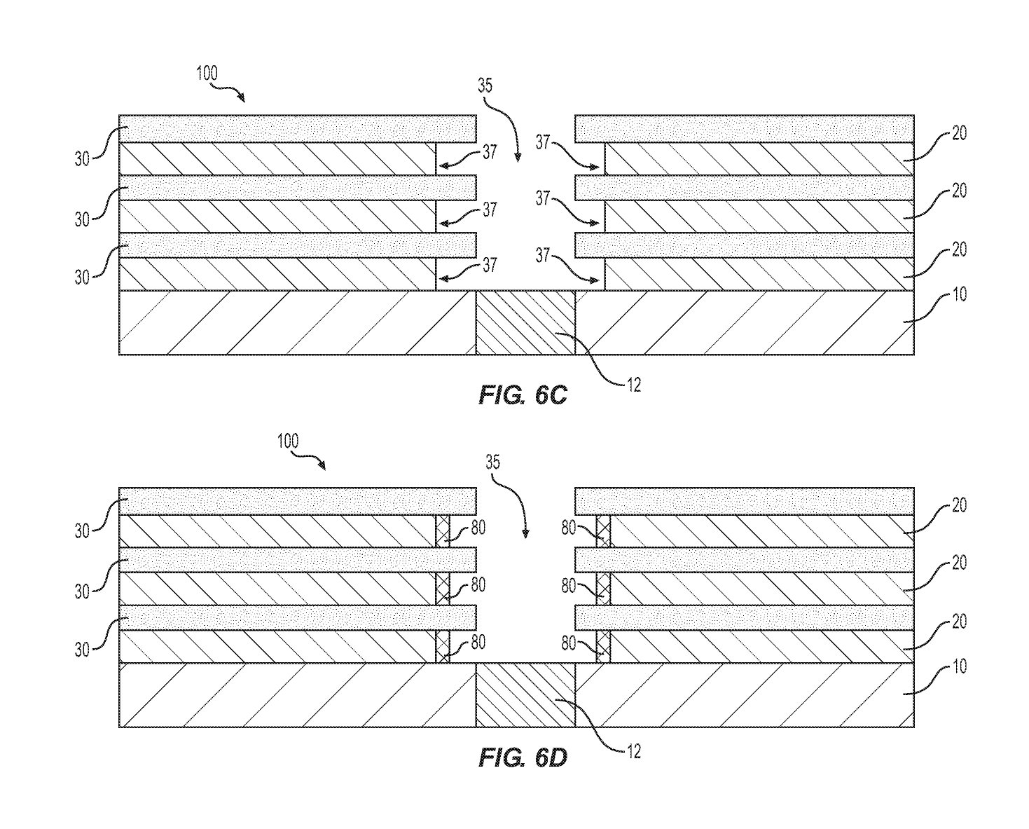

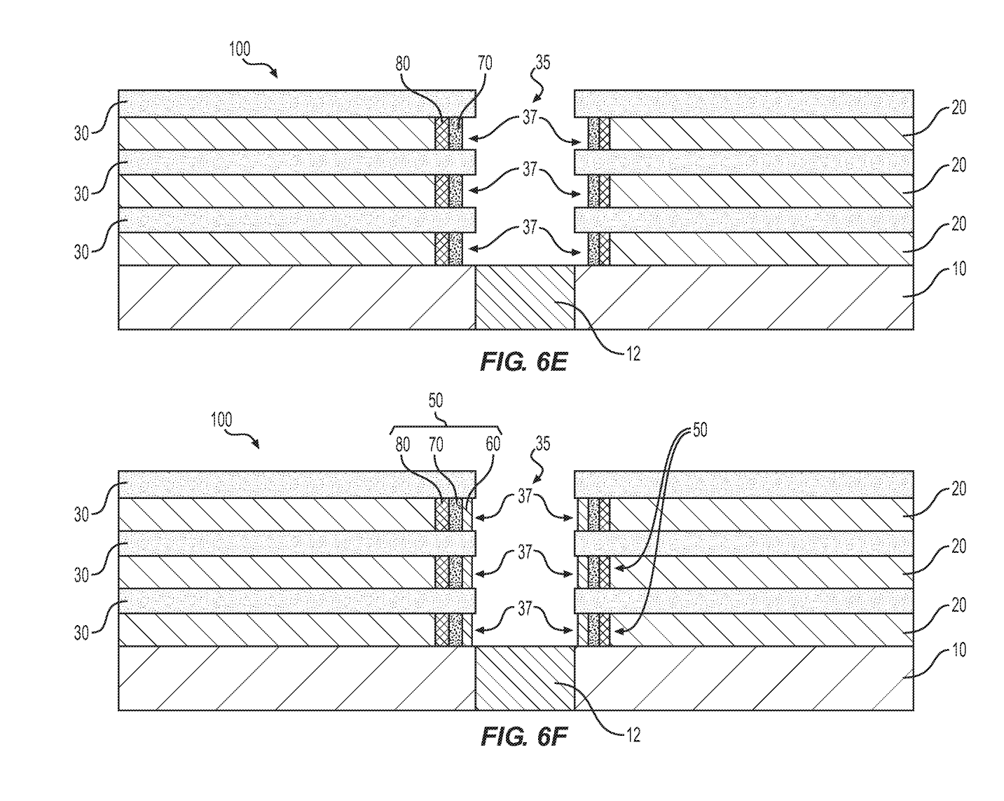

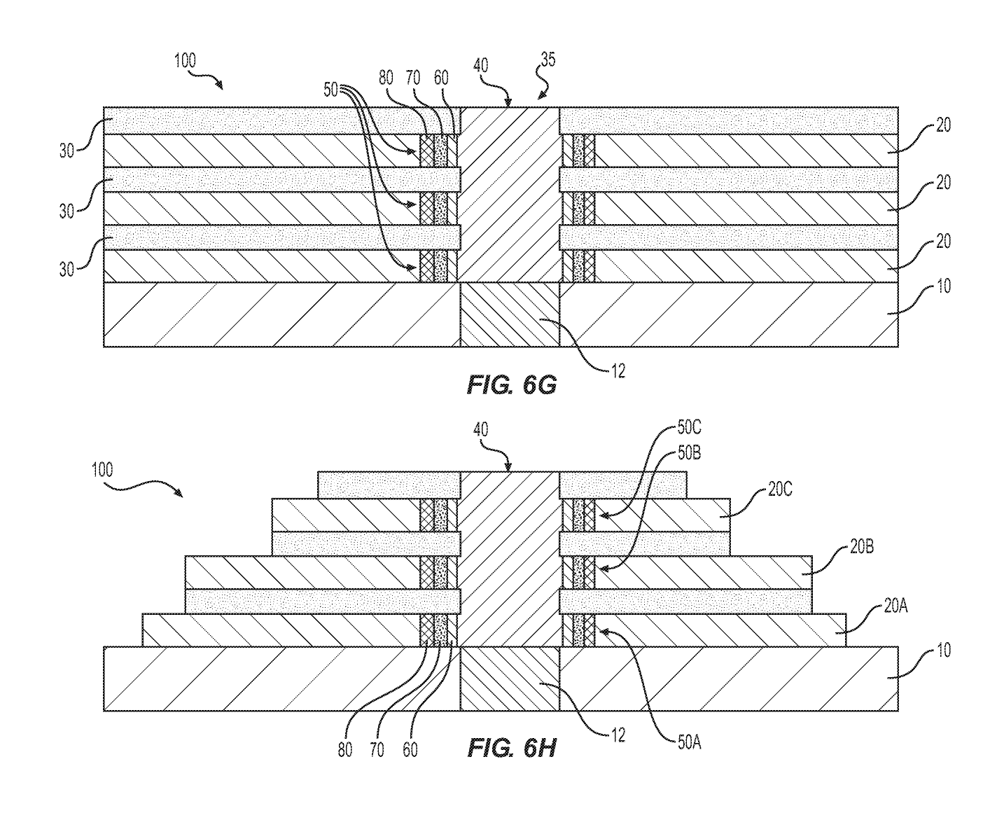

FIG. 5 is a flow chart of a method 200 of fabricating an exemplary magnetoresistive device 100 according to the present disclosure. FIGS. 6A-6H are schematic illustrations of the magnetoresistive device 100 at various stages of the fabrication process. In the description below, reference will be made to FIGS. 5 and 6A-6H. For the sake of brevity, conventional manufacturing techniques related to semiconductor processing may not be described in detail herein. Alternating layers of conductive regions 20 and dielectric regions 30 are formed on a surface of IC 10 having one or more metal pads 12 (step 210). FIG. 6A illustrates an IC device 10 with alternating layers of conductive regions 20 and dielectric regions 30 formed thereon in one exemplary embodiment. Although only one metal pad 12 is depicted in FIG. 6A, those of ordinary skill in the art will readily recognize that IC 10 may include any suitable number of metal pads 12. As explained previously, these metal pads 12 may be part of any interconnect structure (via, line, pad, etc.) of IC 10 that are connected to CMOS circuits (e.g., transistors, diodes, or other selection devices/circuitry, etc.) of IC 10. The conductive regions 20 and dielectric regions 30 may be formed on IC 10 by any now-known of later-developed technique (physical vapor deposition (PVD), chemical vapor deposition (CVD), etc.). In some embodiments, these regions may be sequentially deposited on IC 10 using atomic layer deposition (ALD) (a type of PVD).

An array of vias is then formed by etching through the deposited conductive regions 20 and dielectric regions 30 to expose metal pad 12 (step 220). FIG. 6B illustrates a exemplary via 35 formed through the conductive and dielectric regions 20, 30 that expose a metal pad 12. Any suitable etching process may be used to etch the via 35. For example, in some embodiments, reactive ion etching (RIE) or ion beam etching (IBE) may be used to etch through the metal and dielectric regions 20, 30 and form via 35. As known to those of ordinary skill in the art, IBE and RIE use beams of charged ions (comprising one or more of Argon, Krypton, Xenon, etc.) (reactive charged ions in the case or RIE) to etch through the multiple regions (i.e., regions 20 and 30) to form via 35. As known to those of ordinary skill in the art, in some cases, etching vias 35 may include multiple steps (e.g., photolithography, etc.) that are not described herein. During RIE or IBE, the impact of ions ablate portions of regions 20 and 30 to form via 35. During this process, some of the ablated material may redeposit on the sidewalls of via 35. In some cases, this redeposited layer may affect the electrical and/or magnetic performance of the eventually formed magnetoresistive device (e.g., by forming a conductive path between the various conductive regions 20). Therefore, in some embodiments, during or after the etching process, any redeposited material may be cleaned or otherwise removed from the sidewalls of via 35 by using processes, such as, for example, angled etch, isotropic etch, etc. In some embodiments, this cleaning step may be eliminated or performed on only select portions of sidewalls of via 35. Moreover, in some embodiments, the formation of via 35 may include multiple alternating etching and cleaning steps to form a complete via and expose metal pad 12.

An etching process (e.g., a selective etching process) may then be performed to selectively etch the conductive regions 20 on the sidewalls of via 35 to form annular cavities 37 (step 230). FIG. 6C is an illustration of the magnetoresistive device 100 after etching the conductive regions 20 in via 35. Any etching process that preferentially etches the material of conductive regions 20 (compared to the material of dielectric regions 30) may be used. In some cases, both conductive region 20 and dielectric region 30 (of the via 35 sidewall) may be etched during this step. However, the etch rate of the conductive regions 20 will be higher (significantly higher in some embodiments) than that of dielectric regions 30, to etch or otherwise remove material from conductive regions 20 at rates faster than material is removed from adjacent dielectric regions. In some embodiments, a wet etch process using an etchant that preferentially etches region 20 compared to region 30 (e.g., the etch rate of region 20>etch rate of region 30) may be used. In general, the chemistry of the etchant used depends upon the materials used for regions 20 and 30 and/or desired symmetric or asymmetric etch rates or preferences. In some embodiments, a wet etch process using an etchant comprising of, for example, chlorine, an etchant comprising of a hydroxide and a peroxide (e.g., a mixture of de-ionized water, ammonium hydroxide, and hydrogen peroxide), hydrofluoric acid (HF)+methyltrioxisilane, potassium hydroxide (KOH)+hydrogen peroxide (H₂O₂), piranha solution, etc. may be used. “Handbook of Metal Etchants,” Ed. Perrin Walker, William H. Tarn, CRC Press, 1991, describe several etchants that may be used for this selective etching step. This reference is incorporated by reference in its entirety herein. After selective etching, as illustrated in FIG. 6C, annular cavities 37 are formed on the sidewall of via 35. These annular cavities 37 correspond to areas where the etchant has selectively etched conductive regions 20. Although the annular cavities 37 only are shown in partial cross-section, those of ordinary skill in the art will readily recognize that the annular cavities extend entirely around or substantially around a central axis of via 35.

MTJ bits 50 may then be formed in the annular cavities 37 on the side wall of via 35 (step 240). The MTJ bits 50 may be formed by sequentially forming in annular cavities 37, the multiple regions (i.e., free region 80, intermediate region 70, and fixed region 60) that comprise the MTJ bits 50. FIGS. 6D-6F are schematic illustrations after each of free region 80, intermediate region 70, and fixed region 60 are formed in annular cavities 37. FIG. 6D illustrates the partially-formed magnetoresistive device 100 with a free region 80 formed in annular cavities 37. FIG. 6E shows an intermediate region 70 formed on the free region 80 in annular cavities 37. And, FIG. 6F shows MTJs 50 formed in annular cavities 37 by depositing a fixed region 60 on intermediate region 70. Other regions or layers also may be deposited on or adjacent any of free region 80, intermediate region 70, and/or fixed region 60. Any process that selectively forms the multiple regions of MTJ bits 50 on the material of conductive region 20 (compared to the material of dielectric region 30) may be used to form MTJ bits 50 in annular cavities 37. In some embodiments, a process such as, for example, selective atomic layer deposition (ALD) or atomic scale deposition (ASD) may be used to selectively form MTJ bits 50 in annular cavities 37 by selectively forming the annular magnetic stack that makes up each MTJ bit 50. ALD is a known thin-film deposition technique based on the sequential use of a gas-phase chemical process to selectively deposit/grow materials on selected materials. ALD may make use of chemicals (typically called precursors) that react with the surface of a material to form a surface layer of a different material. Through repeated and/or sequential exposure to suitable precursors, the multiple regions of MTJ bits 50 may be formed in annular cavities 37. As shown in FIG. 6F, an entirety of each MTJ bit may be wholly received within a respective annular cavity 37 such that dielectric regions 30 separate and electrically insulate adjacent MTJ bits 50.

The vias 35 may then be filled with an electrically conductive material (step 250). FIG. 6G illustrates via 35 filled with an electrically conductive material (e.g., Cu, Ta, TaN, Al, Ti, W, etc.) to form electrically conductive via 40. Electrically conductive via 40 may form a first electrical connection to MTJ bits 50 in annular cavities 37. For example, electrically conductive via 40 may form an electrical connection to a first side (e.g., one end, one terminal, etc.) of MTJ bits 50. Via 35 is filled such that the conductive via 40 makes an electrical connection with metal pad 12 of IC 10. Any suitable process, such as, for example, PVD, CVD (e.g., ALD, etc.), plating, etc. may be used to fill via 35. In some embodiments, a chemical mechanical polishing step (CMP) may be performed after filling via 35 to planarize the top surface of the structure and produce a level surface for subsequent processing (e.g., deposition of additional layers, etc.).

One or more etching steps may then be performed to expose areas of the individual conductive regions 20A, 20B, 20C (step 260). These exposed areas of the conductive regions 20A, 20B, 20C may form a second electrical connections to MTJ bits 50 (for example, an electrical connection to a second end (e.g., opposite the first end, opposite terminal, etc.) of the MTJ bits 50). In some embodiments, these etching steps may include multiple lithographic steps (where, for example, selected areas of the structure are covered and selected areas are exposed) to create a patterned structure, and subjecting this patterned structure to an etching operation (e.g., dry etching (such as, for example, RIE, IBE, etc.), wet etching, etc.) to remove material from the exposed areas. In some embodiments, as illustrated in FIG. 6H, the etching may result in a staircase-like structure with selected portions of the individual conductive regions 20A, 20B, 20C exposed. These exposed areas of conductive regions 20A, 20B, 20C may then be used as electrical contacts to access the individual MTJ bits 50A, 50B, 50C. For example, passing a signal (e.g., current) through the exposed area of conductive region 20A, through MTJ bit 50A, and to metal pad 12 by way of conductive via 40, may change the magnetization direction of the free region 80 of MTJ bit 50A. Similar electrical pathways may be formed for each of MTJ bits 50B and 50C. After the vertically stacked annular MTJ bits 50 are formed as described above, additional processing steps (such as, for example, forming a bit contact structure to make electrical contact with the individual MTJ bits 50, etc.) may be performed to fabricate magnetoresistive device 100. Since these additional processing steps are known to those of ordinary skill in the art, they are not described herein for the sake of brevity.

The fabrication method described above with reference to FIGS. 5 and 6A-6H is only exemplary. Many modifications are possible. For example, some of the above-described steps may be modified, eliminated, or otherwise combined with other steps, whether described or not described herein. For example, in some embodiments, the step of etching or otherwise forming annular cavities 37 (step 230, see FIG. 6C) may be eliminated, and resulting MTJ bits 50 (formed on conductive regions 20) may extend radially into via 35. In such cases, for example, an additional step of providing an insulator or insulative layer to isolate each MTJ bit 50 from adjacent MTJ bits 50 may be provided.

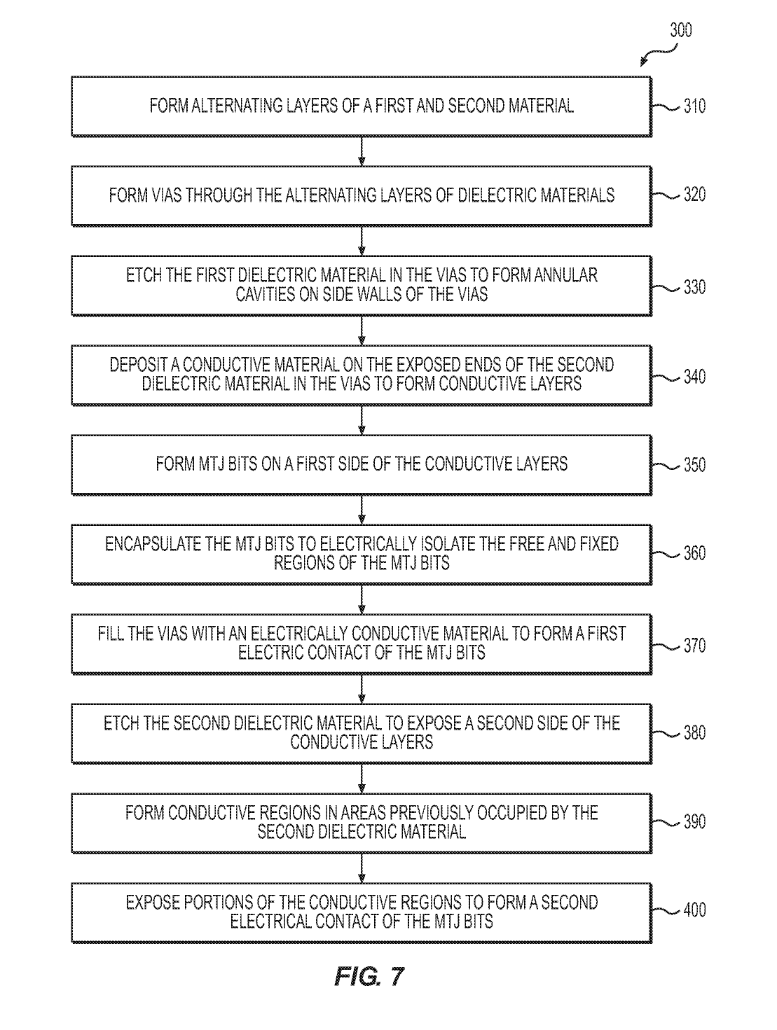

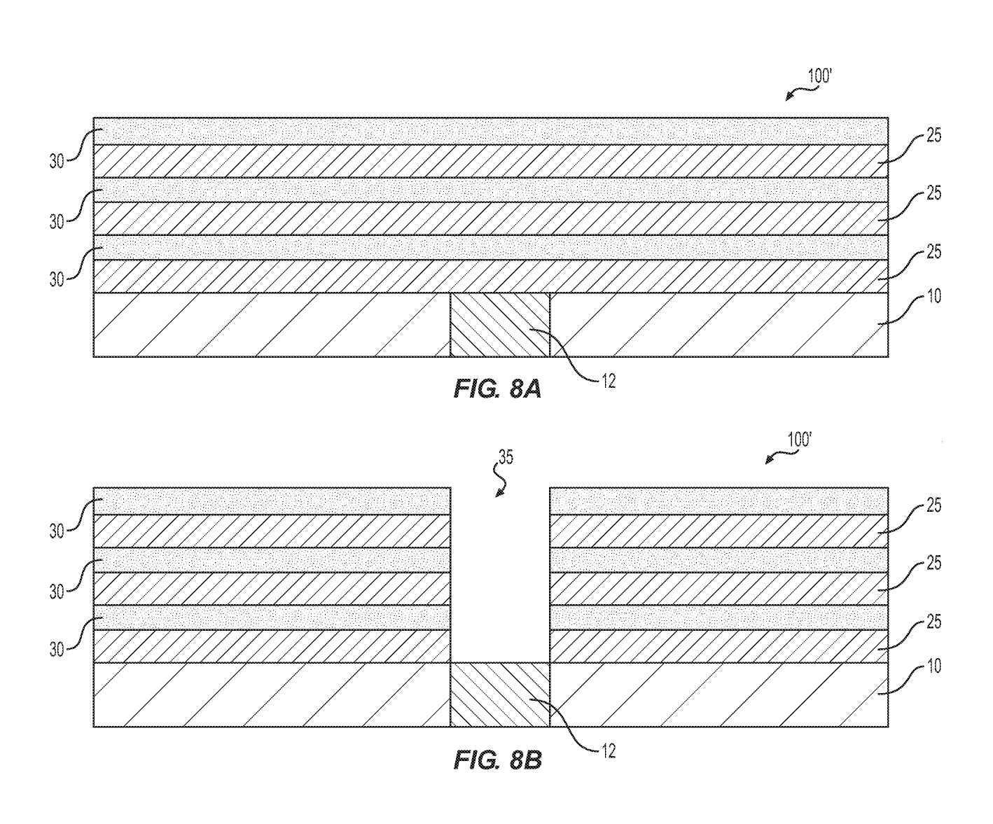

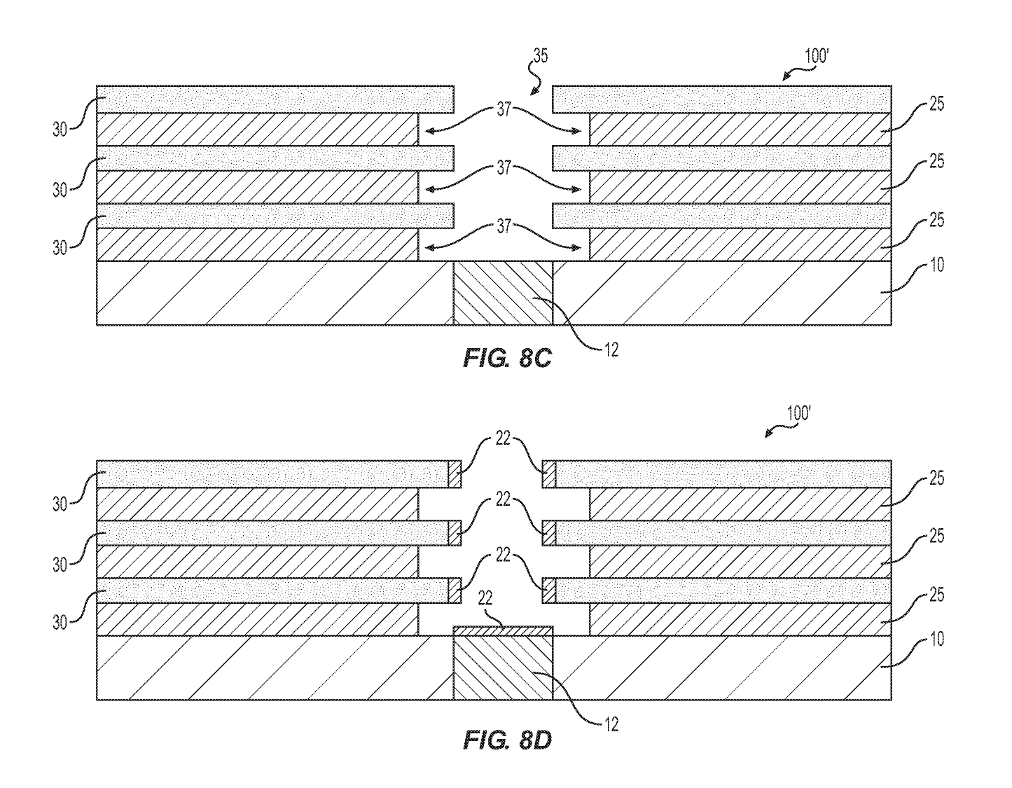

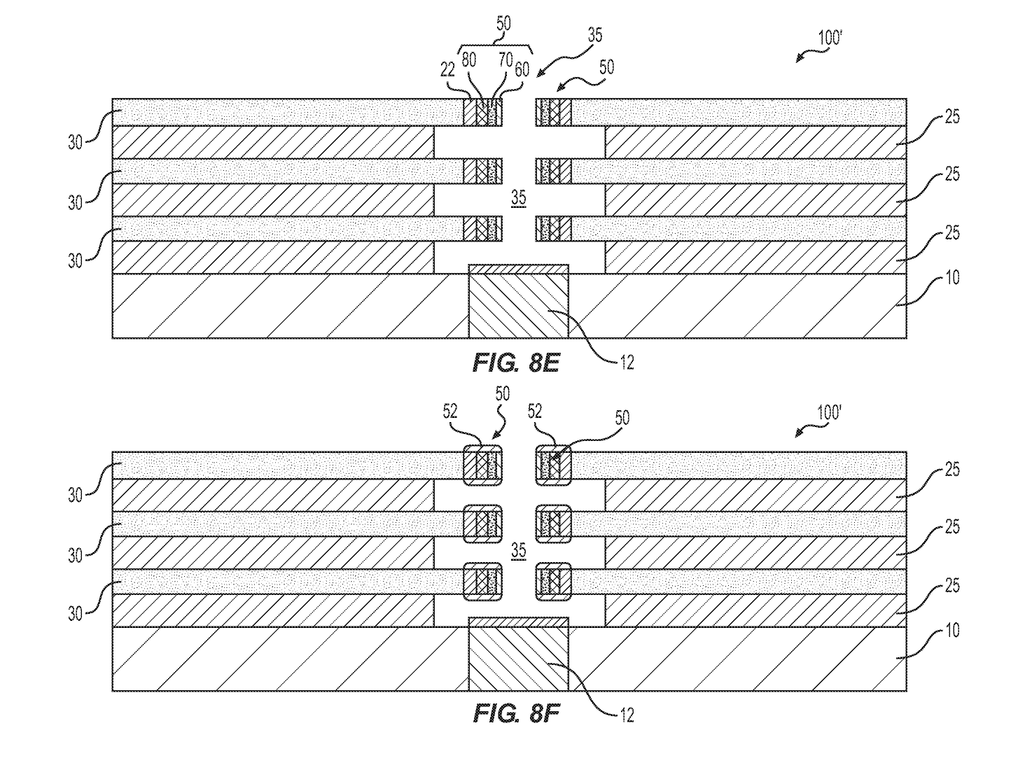

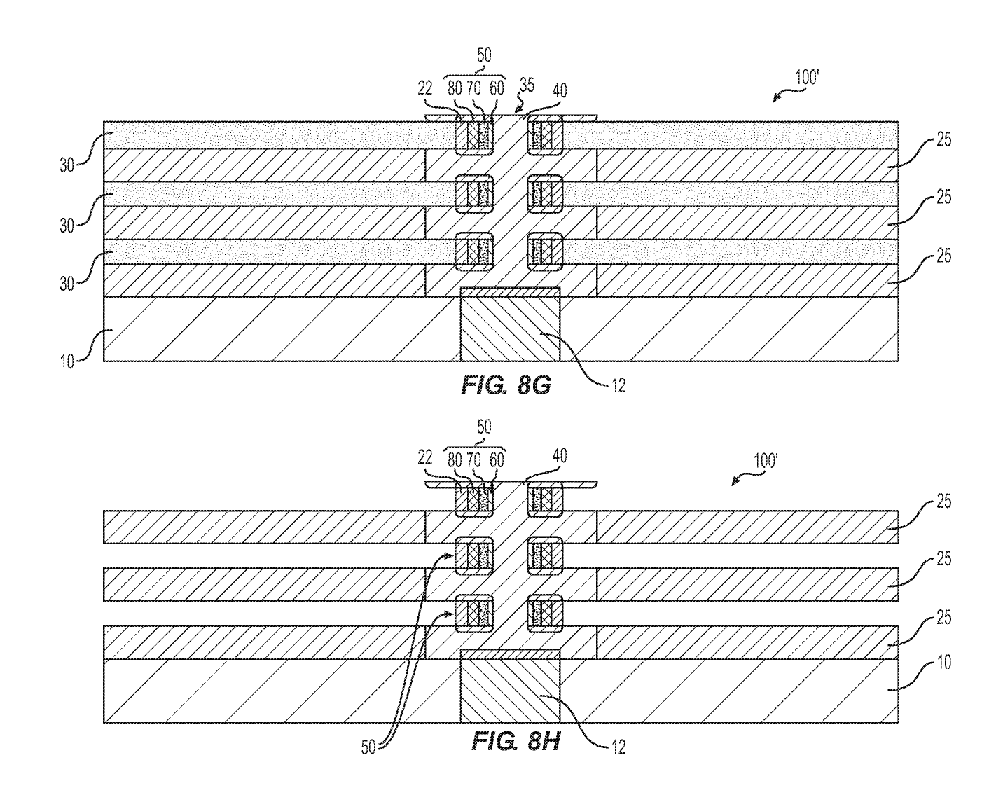

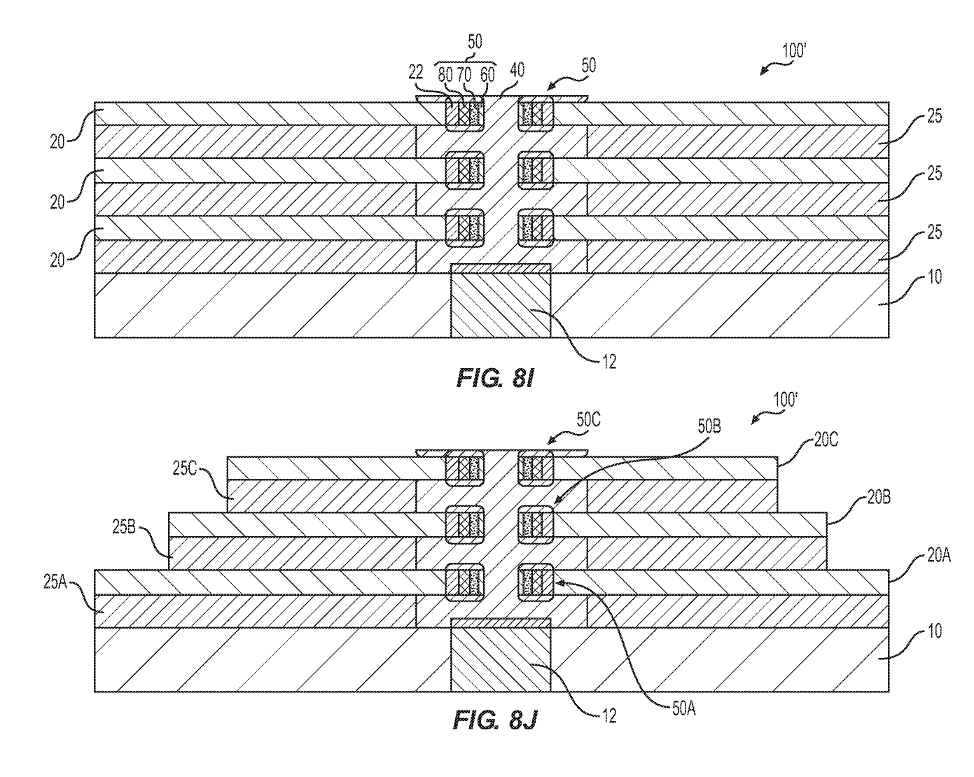

FIG. 7 is a flow chart of another exemplary method 300 of fabricating an exemplary magnetoresistive device 100′ according to the present disclosure. FIGS. 8A-8J are schematic illustrations of the magnetoresistive device 100′ at various stages of the fabrication process. In the description below, reference will be made to FIGS. 7 and 8A-8J. In the description below, processes steps that are similar to the previously described steps of method 200 (FIGS. 5 and 6A-6H) will not be described again. Alternating layers of two different dielectric materials—dielectric region 30 and dielectric region 25 are formed or provided (e.g., deposited) on a surface of IC 10 having metal pads 12 (step 310). FIG. 8A is a schematic illustration of alternating dielectric regions 25, 30 on IC die 10. Dielectric regions 30 and 25 may include now-known or future-developed electrically insulating materials (including, e.g., oxides, nitrides, carbonitrides, etc.). In some embodiments, dielectric regions 25 and 30 may include materials having different etch rates (in some embodiments, substantially different etch rates). In some embodiments, dielectric regions 25 and 30 may include a different one of (or a different combination of) Silicon Nitride (e.g., Si₃N₄, SiN, etc.), Silicon Oxide (e.g., SiO₂, SiOₓ, etc.), a low-k (inter layer dielectric) ILD material (e.g., carbon doped SiO₂ (SiOC), Carbon Doped Oxide (CDO), Organo Silicate Glass (OSG) spin-on organics, etc.), aluminum oxide (such as Al₂O₃), magnesium oxide (such as MgO), tetraethoxysilane (TEOS), etc. In some embodiments, dielectric region 25 may include a nitride dielectric material and dielectric region 30 may include an oxide dielectric material. Any suitable deposition process may be used to deposit or otherwise form dielectric regions 25 and 30 on IC 10.

An array of vias 35 (only one shown) may then be etched through the multi-layer stack of dielectric regions 25 and 30 to expose metal pads 12 of IC 10 (step 320). FIG. 8B illustrates a via 35 formed through dielectric regions 25 and 30 to expose metal pad 12. Even though only one metal pad 12 is shown in FIGS. 8A and 8B, those of ordinary skill in the art will readily recognize that IC 10 may include any suitable number of metal pads 12. Any etching process (e.g., RIE, IBE, wet etching, etc.) may be used to form via 35. As described previously, in some embodiments, the via etching process may include processes such as, for example, sidewall cleaning, etc. to remove redeposited material from the sidewall of via 35. A selective etch process (e.g., a selective wet etch process) may then be carried out to selectively etch annular cavities 37 in dielectric region 25 (step 330). FIG. 8C is a schematic illustration of the partially formed magnetoresistive device 100′ with annular cavities 37 on the side wall of via 35. Any suitable etchant which preferentially etches dielectric region 25 (compared to dielectric region 30) may be used as the etchant. In embodiments where dielectric region 25 includes a nitride, phosphoric acid (H₃PO₄) may be used as the etchant to selectively etch annular cavities 37 in the nitride dielectric region 25 (by, for example, hot phosphoric acid etching). An electrically conductive material may then be deposited on the exposed ends of dielectric region 30 in via 35 to form conductive layers 22 (step 340). FIG. 8D illustrates the conductive layers 22 formed on the exposed dielectric regions 30. Any suitable process may be used to deposit conductive layer 22. In some embodiments, a line-of-sight material deposition technique (such as, for example, sputtering) may be used to deposit conductive layers 22 on surfaces within via 35 that are in the line of sight of the sputtering target. Any suitable electrically conductive material may be used to form conductive layer 22. In some embodiments, conductive layer 22 may include one or more of Copper (Cu), Tantalum (Ta), Tantalum Nitride (TaN), Aluminum (Al), Titanium (Ti), Tungsten (W), etc. As shown in FIG. 8D, the formation of a conductive layer 22 on exposed portions of dielectric regions 30 may result in the formation of a conductive layer 22 on metal pad 12.

MTJ bits 50 may then be formed on the conductive layers 22 deposited on the exposed end portions of dielectric regions 30 in via 35 (step 350). Forming the MTJ bits 50 may include sequentially depositing the multiple regions (e.g., free region 80, intermediate region 70, and fixed region 60) of MTJ bits 50 on the conductive layers 22. FIG. 8E is a schematic illustration of MTJ bits 50 formed on conductive layers 22 in via 35. Any suitable process (e.g., ALD, ASD, etc.) that selectively forms these regions on conductive regions 22 may be used to form MTJ bits 50. In some embodiments, the conductive region 22 on metal pad 12 may be masked or otherwise covered (e.g., using an encapsulant) prior to forming MTJ bits 50 on conductive regions 22 at the ends of dielectric regions 30. This encapsulant may be subsequently removed (e.g., by etching). Alternatively, or additionally, in some embodiments, the different regions of MTJ bits 50 may be formed on all conductive regions 22 in via 35 (including the conductive region 22 formed on metal pad 12). The MTJ bit 50 formed on metal pad 12 may then be removed.

The formed MTJ bits 50 may then be encapsulated using a dielectric material 52 to electrically isolate fixed regions 60 from free regions 80 of MTJ bits 50 (step 360). FIG. 8F schematically illustrates the encapsulated MTJ bits 50. Any electrically insulating material (including any of the materials described with reference to dielectric regions 25 and 30) may be used as dielectric material 52. In some embodiments, encapsulant 52 may only be deposited on the annular top and bottom surfaces (i.e., the horizontal surfaces in FIG. 8F) of MTJ bits 50. Alternatively, in some embodiments, encapsulant 52 may be deposited on all exposed surfaces of MTJ bits 50, and the deposited encapsulant from some or all of the exposed surfaces of fixed region 60 (or one or more of the surfaces of the region of MTJ bit 50 that is not attached to dielectric region 30) may then be removed (etched, etc.).

Via 35 then may be filled with an electrically conductive material (e.g., Cu, Ta, TaN, Al, Ti, W, etc.) to form conductive via 40 (step 370). FIG. 8G schematically illustrates the partially formed magnetoresistive device 100′ with the filled via 35. Via 35 is filled such that the conductive via 40 makes an electrical connection with metal pad 12 of IC 10 and the exposed surfaces of fixed region 60 of MTJ bits 50. Any suitable process, such as, for example, PVD, CVD (e.g., ALD, etc.), plating, etc. may be used to fill via 35. In some embodiments, a chemical mechanical polishing step (CMP) may be performed after filling via 35 to planarize the top surface of the structure and produce a level surface for subsequent processing (e.g., deposition of additional layers, etc.).

Dielectric regions 30 may then be removed by etching (step 380). FIG. 8H schematically illustrates the partially formed magnetoresistive device 100′ with dielectric regions 30 removed. Any suitable etching process may be used to remove dielectric regions 30. In embodiments, where dielectric regions 30 include an oxide material, an oxide etching process may be used to remove dielectric region 30. As illustrated in FIG. 8H, removal of dielectric regions 30 will expose surfaces of the conductive layer 22 that were previously in contact with dielectric regions 30. Conductive regions 20 may then be formed (e.g., deposited) in areas that were previously occupied by dielectric regions 30 (step 390). FIG. 8I illustrates conductive regions 20 formed on the partially formed magnetoresistive device 100′. These conductive regions 20 will make electrical contact with the free regions 60 of MTJ bits 50 through conductive layers 22.

Selected areas (e.g., areas opposite to the MTJ bits 50) of the individual conductive regions 20A, 20B, 20C may then be exposed by etching (e.g., RIE, IBE, etc.) (Step 400). In some embodiments, as illustrated in FIG. 8J, for example, the etching may result in a staircase-like structure with selected regions of the individual conductive regions 20A, 20B, 20C exposed. These exposed areas of conductive regions 20A, 20B, 20C may then be used as electrical contacts or pathways to electrically access the individual MTJ bits 50A, 50B, 50C. For example, passing a signal (e.g., current) through the exposed area of conductive region 20A may change the magnetization direction of the free region 80 of MTJ bit 50A. After the vertically stacked annular MTJ bits 50 are formed as described above, additional processing steps (such as, for example, forming a bit contact structure to make electrical contact with the individual MTJ bits 50, etc.) may be performed to fabricate the magnetoresistive device 100′. Since these additional processing steps are known to those of ordinary skill in the art, they are not described herein for the sake of brevity.

It should be appreciated that the fabrication methods 200 and 300 and processes described above are merely exemplary. In some embodiments, the method(s) may include a number of additional or alternative steps, and in some embodiments, one or more of the described steps may be omitted. Any described step may be omitted or modified, or other steps added, as long as the intended result and/or functionality of the subsequently formed magnetoresistive device remains substantially unaltered. Although a certain order is described or implied in the described method, in general, the steps of the described method need not be performed in the illustrated and described order. Further, the described method may be incorporated into a process of fabricating an MTJ bit for the described magnetoresistive device. Since the additional steps needed to form MTJ bits are known to those of ordinary skill in the art, they are not described herein. Additionally, the described method may be incorporated into a more comprehensive procedure or process having additional functionality not described herein.

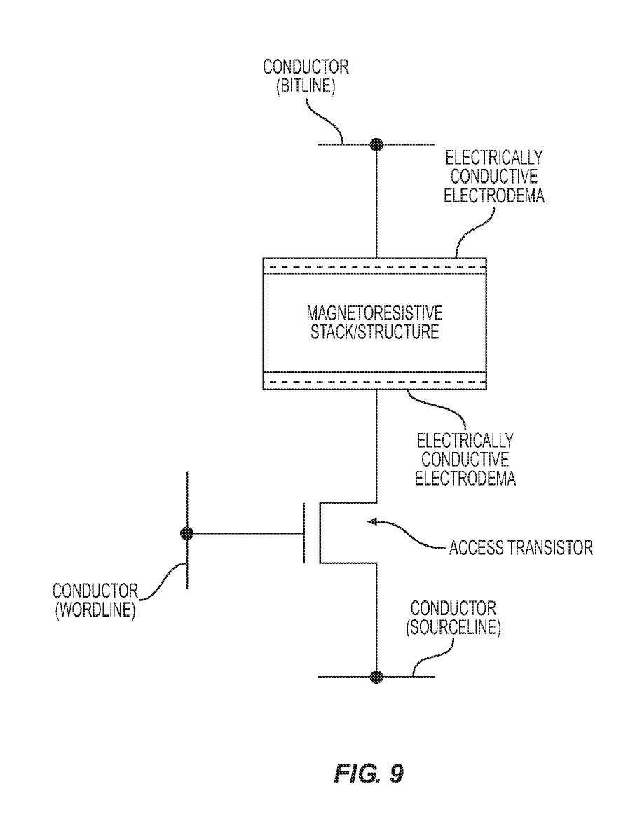

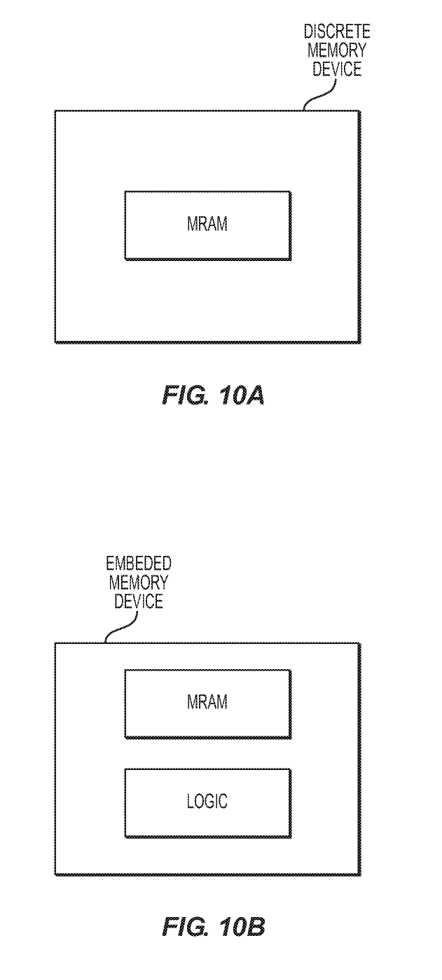

As alluded to above, the magnetoresistive devices 100, 100′ (formed using vertically stacked annular MTJ bits 50) may include a sensor architecture or a memory architecture (among other architectures). For example, in magnetoresistive devices having a memory configuration, the MTJ bits 50 may be electrically connected to an access transistor (or other select device, e.g., a diode) and configured to couple or connect to various conductors, which may carry one or more control signals, as shown in FIG. 9. Those conductors may be connected to various memory architecture or associated circuitry. The magnetoresistive devices may be used in any suitable application, including, e.g., in a memory configuration. In such instances, the magnetoresistive devices may be formed as integrated circuits comprising a discrete memory device (e.g., as shown in FIG. 10A) or an embedded memory device having a logic therein (e.g., as shown in FIG. 10B), each including MRAM, which, in one embodiment is representative of one or more arrays of MRAM having a plurality of magnetoresistive stacks/structures, according to certain aspects of certain embodiments disclosed herein.

In some embodiments, a magnetoresistive device is disclosed. The magnetoresistive device may include a plurality of magnetic tunnel junction (MTJ) bits arranged one on top of another. Each MTJ bit of the plurality of MTJ bits may be annular-shaped and include an inner end positioned radially inwards of an outer end. A common electrically conductive via may be in contact with the inner end of each MTJ bit of the plurality of MTJ bits.

Various embodiments of the disclosed magnetoresistive device may include one or more of the following aspects: one or more dielectric layers separating the plurality of MTJ bits; an electrical conductor may be in contact with the outer end of each MTJ bit of the plurality of MTJ bits; each MTJ bit of the plurality of MTJ bits may include a magnetically free region and a magnetically fixed region separated by an intermediate layer; each MTJ bit of the plurality of MTJ bits may include an annular-shaped magnetically free region and an annular-shaped magnetically fixed region radially spaced apart from each other and separated by an annular-shaped intermediate layer; each MTJ bit of the plurality of MTJ bits may include an annular-shaped magnetically free region and an annular-shaped magnetically fixed region separated from each other by an annular-shaped intermediate layer, wherein the magnetically free region is positioned radially inwards of the magnetically fixed region; each MTJ bit of the plurality of MTJ bits may include an annular-shaped magnetically free region and an annular-shaped magnetically fixed region separated from each other by an annular-shaped intermediate layer, wherein the magnetically fixed region is positioned radially inwards of the magnetically free region; the plurality of MTJ bits may include a first MTJ bit positioned above a second MTJ bit, wherein the outer end of the first MTJ bit is positioned radially inwards of the outer end of the second MTJ bit; the plurality of MTJ bits may form a first vertically stacked array of MTJ bits, and the device may further include a second vertically stacked array of MTJ bits horizontally spaced apart from the first vertically stacked array of MTJ bits, the second vertically stacked array of MTJ bits may include a second plurality of annular-shaped MTJ bits arranged one on top of another; the common electrically conductive via may include at least one of copper, tantalum, tantalum nitride, aluminum, and tungsten.

In some embodiments, a magnetoresistive device is disclosed. The magnetoresistive device may include an annular-shaped magnetic tunnel junction (MTJ) bit having an inner end and an outer end. The MTJ bit may include an annular-shaped magnetically free region and an annular-shaped magnetically fixed region separated by an annular-shaped intermediate layer. A first electrical conductor may be in electrical contact with the inner end of the MTJ bit, and a second electrical conductor may be in electrical contact with the outer end of the MTJ bit.

Various embodiments of the disclosed magnetoresistive device may include one or more of the following aspects: the annular-shaped MTJ bit may be a first annular-shaped MTJ bit, and wherein the device may further include a second annular-shaped MTJ bit having an inner end and an outer end stacked above the first annular-shaped MTJ bit and separated from the first annular-shaped MTJ bit by a dielectric layer. The inner end of the second annular-shaped MTJ bit may be in electrical contact with the first electrical conductor; the annular-shaped MTJ bit is a first annular-shaped MTJ bit, and the device may further include a second annular-shaped MTJ bit having an inner end and an outer end stacked above the first annular-shaped MTJ bit and separated from the first annular-shaped MTJ bit by a dielectric layer, the outer end of the second annular-shaped MTJ bit may be positioned radially inwards of the outer end of the first annular-shaped MTJ bit; the annular-shaped MTJ bit is a first annular-shaped MTJ bit, and the device may further include a second annular-shaped MTJ bit having an inner end and an outer end horizontally spaced-apart from the first annular-shaped MTJ bit; the annular-shaped magnetically free region may be positioned radially inwards of the annular-shaped magnetically fixed region; the annular-shaped magnetically fixed region may be positioned radially inwards of the annular-shaped magnetically free region.

In some embodiments, a magnetoresistive device is disclosed. The magnetoresistive device may include a first vertically-stacked array of magnetic tunnel junction (MTJ) bits including a plurality of annular-shaped MTJ bits arranged one on top of another and separated from each other by a dielectric layer. Each MTJ bit of the plurality of MTJ bits may include (a) an inner end positioned radially inwards of an outer end, and (b) an annular-shaped magnetically free region and an annular-shaped magnetically fixed region separated from each other by an annular-shaped intermediate layer. The magnetoresistive device may also include a second vertically-stacked array of MTJ bits horizontally spaced apart from the first vertically-stacked array of MTJ bits. Each MTJ bit of the second vertically-stacked array of MTJ bits may include an annular-shaped magnetically free region and an annular-shaped magnetically fixed region separated from each other by an annular-shaped intermediate layer.

Various embodiments of the disclosed magnetoresistive device may include one or more of the following aspects: a common electrically conductive via in contact with the inner end of each MTJ bit of the first vertically-stacked array of MTJ bits; the first vertically-stacked array of MTJ bits may include a first MTJ bit positioned above a second MTJ bit, wherein the outer end of the first MTJ bit is positioned radially inwards of the outer end of the second MTJ bit; each MTJ bit of the second vertically-stacked array of MTJ bits includes an inner end and an outer end, and a common electrically conductive via in electrical contact with the inner end of each MTJ bit of the second vertically-stacked array of MTJ bits.

Although various embodiments of the present disclosure have been illustrated and described in detail, it will be readily apparent to those skilled in the art that various modifications may be made without departing from the present disclosure.

What is claimed is:

1. A magnetoresistive device, comprising:
a plurality of magnetic tunnel junction (MTJ) bits arranged one on top of another, wherein each MTJ bit of the plurality of MTJ bits is annular-shaped and includes an inner end positioned radially inwards of an outer end; and
a common electrically conductive via in contact with the inner end of each MTJ bit of the plurality of MTJ bits.

2. The magnetoresistive device of claim 1, further including one or more dielectric layers separating the plurality of MTJ bits.

3. The magnetoresistive device of claim 1, further including an electrical conductor in contact with the outer end of each MTJ bit of the plurality of MTJ bits.

4. The magnetoresistive device of claim 1, wherein each MTJ bit of the plurality of MTJ bits includes a magnetically free region and a magnetically fixed region separated by an intermediate layer.

5. The magnetoresistive device of claim 1, wherein each MTJ bit of the plurality of MTJ bits includes an annular-shaped magnetically free region and an annular-shaped magnetically fixed region radially spaced apart from each other and separated by an annular-shaped intermediate layer.

6. The magnetoresistive device of claim 1, wherein each MTJ bit of the plurality of MTJ bits includes an annular-shaped magnetically free region and an annular-shaped magnetically fixed region separated from each other by an annular-shaped intermediate layer, wherein the magnetically free region is positioned radially inwards of the magnetically fixed region.

7. The magnetoresistive device of claim 1, wherein each MTJ bit of the plurality of MTJ bits includes an annular-shaped magnetically free region and an annular-shaped magnetically fixed region separated from each other by an annular-shaped intermediate layer, wherein the magnetically fixed region is positioned radially inwards of the magnetically free region.

8. The magnetoresistive device of claim 1, wherein the plurality of MTJ bits includes a first MTJ bit positioned above a second MTJ bit, wherein the outer end of the first MTJ bit is positioned radially inwards of the outer end of the second MTJ bit.

9. The magnetoresistive device of claim 1, wherein the plurality of MTJ bits form a first vertically stacked array of MTJ bits, and wherein the device further includes a second vertically stacked array of MTJ bits horizontally spaced apart from the first vertically stacked array of MTJ bits, the second vertically stacked array of MTJ bits including a second plurality of annular-shaped MTJ bits arranged one on top of another.

10. The magnetoresistive device of claim 1, wherein the common electrically conductive via includes at least one of copper, tantalum, tantalum nitride, aluminum, and tungsten.

11. A magnetoresistive device, comprising:
an annular-shaped magnetic tunnel junction (MTJ) bit having an inner end and an outer end, wherein the MTJ bit includes an annular-shaped magnetically free region and an annular-shaped magnetically fixed region separated by an annular-shaped intermediate layer;
a first electrical conductor in electrical contact with the inner end of the MTJ bit; and
a second electrical conductor in electrical contact with the outer end of the MTJ bit.

12. The magnetoresistive device of claim 11, wherein the annular-shaped MTJ bit is a first annular-shaped MTJ bit, and wherein the device further includes a second annular-shaped MTJ bit having an inner end and an outer end stacked above the first annular-shaped MTJ bit and separated from the first annular-shaped MTJ bit by a dielectric layer, the inner end of the second annular-shaped MTJ bit being in electrical contact with the first electrical conductor.

13. The magnetoresistive device of claim 11, wherein the annular-shaped MTJ bit is a first annular-shaped MTJ bit, and wherein the device further includes a second annular-shaped MTJ bit having an inner end and an outer end stacked above the first annular-shaped MTJ bit and separated from the first annular-shaped MTJ bit by a dielectric layer, the outer end of the second annular-shaped MTJ bit being positioned radially inwards of the outer end of the first annular-shaped MTJ bit.

14. The magnetoresistive device of claim 11, wherein the annular-shaped MTJ bit is a first annular-shaped MTJ bit, and wherein the device further includes a second annular-shaped MTJ bit having an inner end and an outer end horizontally spaced-apart from the first annular-shaped MTJ bit.

15. The magnetoresistive device of claim 11, wherein the annular-shaped magnetically free region is positioned radially inwards of the annular-shaped magnetically fixed region.

16. The magnetoresistive device of claim 11, wherein the annular-shaped magnetically fixed region is positioned radially inwards of the annular-shaped magnetically free region.

17. A magnetoresistive device, comprising:
a first vertically-stacked array of magnetic tunnel junction (MTJ) bits including a plurality of annular-shaped MTJ bits arranged one on top of another and separated from each other by a dielectric layer, wherein each MTJ bit of the plurality of MTJ bits includes (a) an inner end positioned radially inwards of an outer end, and (b) an annular-shaped magnetically free region and an annular-shaped magnetically fixed region separated from each other by an annular-shaped intermediate layer; and
a second vertically-stacked array of MTJ bits horizontally spaced apart from the first vertically-stacked array of MTJ bits, each MTJ bit of the second vertically-stacked array of MTJ bits including an annular-shaped magnetically free region and an annular-shaped magnetically fixed region separated from each other by an annular-shaped intermediate layer.

18. The magnetoresistive device of claim 1, further including a common electrically conductive via in contact with the inner end of each MTJ bit of the first vertically-stacked array of MTJ bits.

19. The magnetoresistive device of claim 17, wherein the first vertically-stacked array of MTJ bits includes a first MTJ bit positioned above a second MTJ bit, and wherein the outer end of the first MTJ bit is positioned radially inwards of the outer end of the second MTJ bit.

20. The magnetoresistive stack of claim 17, wherein each MTJ bit of the second vertically-stacked array of MTJ bits includes an inner end and an outer end, and a common electrically conductive via in electrical contact with the inner end of each MTJ bit of the second vertically-stacked array of MTJ bits.
